(19) United States
(12) Patent Application Publication
(10) Pub. No.: US 2009/0166693 A1
(43) Pub. Date: Jul. 2, 2009

(54) Image Sensor and Manufacturing Method Thereof

(76) Inventor: Jong Min Kim, Guro-gu (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/269,118

(22) Filed: Nov. 12, 2008

(30) Foreign Application Priority Data
Dec. 27, 2007 (KR) 10-2007-0138549

(51) Int. Cl. H01L 27/146; H01L 31/18

(52) U.S. Cl. 257/292; 438/59; 257/E27.133

(57) ABSTRACT

An image sensor and manufacturing method thereof are provided. The image sensor can include a gate on a semiconductor substrate, first and second p-type doping areas below the gate, a third p-type doping area adjacent to the first p-type doping area, and a fourth p-type doping area adjacent to the third p-type doping area. An n-type doping area can be provided in the semiconductor substrate such that at least a portion of the n-type doping area is disposed below the first, third, and fourth p-type doping areas. A floating diffusion area can be provided adjacent to the second p-type doping area.

### CROSS-REFERENCE TO RELATED APPLICATION

The present application claims the benefit under 35 U.S.C. § 119 of Korean Patent Application No. 10-2007-0138549, filed Dec. 27, 2007, which is hereby incorporated by reference in its entirety.

### BACKGROUND

An image sensor is a semiconductor device for converting an optical image into an electric signal. An image sensor can be categorized as a charge coupled device (CCD) image sensor or a complementary metal oxide semiconductor (CMOS) image sensor.

A CMOS image sensor typically employs a switching mode to sequentially detect output by providing metal oxide semiconductor (MOS) transistors corresponding to the number of pixels through CMOS technology, and using peripheral devices, such as control circuits and signal processing circuits.

Also, a CMOS image sensor generally includes a photodiode for receiving light to generate photocharges and a MOS transistor arranged according to unit pixels.

A MOS transistor circuit for a unit pixel typically includes a transfer transistor for transferring photocharges collected at the photodiode to a floating diffusion region, a reset transistor for setting electric potential of the floating diffusion region to a desired value and for exhausting charges to reset the floating diffusion region, an access transistor for receiving the voltage of the floating diffusion region to serve as a source follow buffer amplifier, and a select transistor for performing switching for addressing.

Additionally, a transfer transistor generally includes a gate, a channel through which charges are shifted, and a drain used as the floating diffusion region.

During operation of a transfer transistor, if light is transferred to the photodiode and photocharges are generated, the gate of the transfer transistor is turned on. Then, threshold voltage adjusted by the channel is reduced so that the charges generated from the photodiode are shifted to the floating diffusion region through the channel.

In image sensors, it is important to have superior transmission properties between the channel of the transfer transistor and an n-type doping area of the photodiode source. When the transistor is turned off, charges existing in the channel must be inhibited from flowing back toward the photodiode in order to improve electron transmission properties. If charges flow back toward the photodiode, noise or image lag may occur.

### BRIEF SUMMARY

Embodiments of the present invention provide an image sensor and manufacturing method thereof. The image sensor can exhibit improved electron transmission efficiency by adjusting doping concentration of a channel area.

In one embodiment, an image sensor can include: a gate on a semiconductor substrate; a first p-type doping area below the gate; a second p-type doping area below the gate and adjacent to the first p-type doping area; a third p-type doping area adjacent to the first p-type doping area at an opposite side from the second p-type doping area; a fourth p-type doping area adjacent to the third p-type doping area; an n-type doping area disposed in the semiconductor substrate such that at least a portion of the n-type doping area is below the first, third, and fourth p-type doping areas; and a floating diffusion area adjacent to the second p-type doping area.

In another embodiment, a method of manufacturing an image sensor can include: forming an n-type doping area in a semiconductor substrate; forming a first p-type doping area on the n-type doping area; forming a second p-type doping area at a first side of the first p-type doping area; forming a gate on at least a portion of the first p-type doping area and at least a portion of the second p-type doping area; forming a third p-type doping area on the n-type doping area at a second side of the first p-type doping area; forming a fourth p-type doping area on the n-type doping area at a side of the third p-type doping area; and forming a floating diffusion area on the second p-type doping area at a side of the gate.

### BRIEF DESCRIPTION OF THE DRAWINGS

FIGS. 1 to 5 are cross-sectional views showing a manufacturing method of an image sensor according to an embodiment of the present invention.

FIG. 6 is a graph showing (a) doping concentration as a function of position for an image sensor according to embodiment of the present invention; and (b) showing potential as a function of position for an image sensor according to embodiment of the present invention.

### DETAILED DESCRIPTION

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

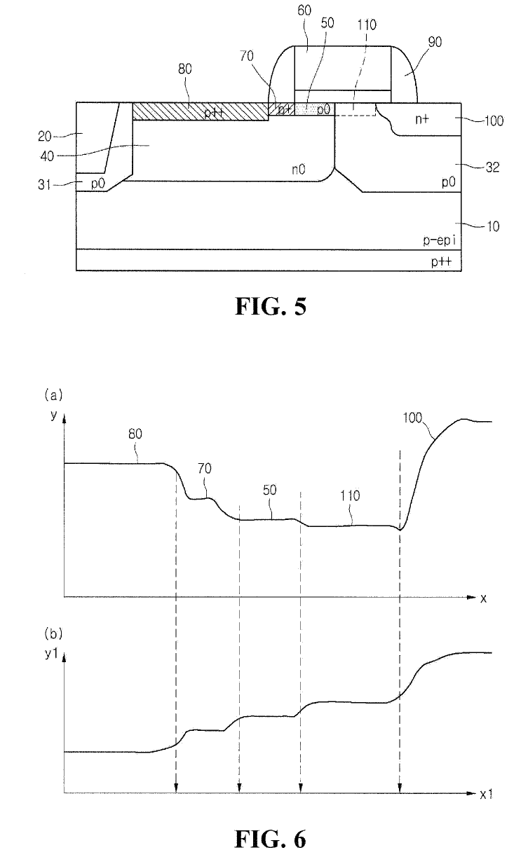

FIG. 5 is a cross-sectional view showing an image sensor according to an embodiment of the present invention.

Referring to FIG. 5, an image sensor can include a gate 60 on a semiconductor substrate 10, a first p-type doping area 50 and a second p-type doping area 110 disposed below the gate 60, a third p-type doping area 70, a fourth p-type doping area 80, an n-type doping area 40, and a floating diffusion area 100. The third p-type doping area 70 can be disposed in the semiconductor substrate 10 adjacent to a side of the first p-type doping area 50. Also, the fourth p-type doping area 80 can be disposed in the semiconductor substrate 10 adjacent to a side of the third p-type doping area 70. The n-type doping area 40 can be disposed in the semiconductor substrate 10 to a depth that is greater than the depth of the third p-type doping area 70 and the first p-type doping area 50. The n-type doping area 40 can also be disposed below the first p-type doping area 50, the third p-type doping area 70, and the fourth p-type doping area 80. The floating diffusion area 100 can be disposed on the semiconductor substrate 10 at a side of the gate 60. The floating diffusion area 100 can define a side boundary of the second p-type doping area 110.

In an embodiment, the semiconductor substrate 10 can be a heavily doped p-type substrate (p++). A lightly doped p-type epitaxial layer can be disposed on the semiconductor substrate 10 and can be formed through an epitaxial process. The semiconductor substrate 10 can includes an isolation layer 20 for isolating an active area from a field area. Additionally, the gate 60 can include spacers 90, and at least a portion of the third p-type doping area 70 can be under one of the spacers 90.

A first p-type well area 31 and a second p-type well area 32 can be disposed at sides of the n-type doping area 40, helping to isolate the n-type doping area 40. That is, the first p-type well area 31 can be disposed at one side of the n-type doping area 40, and the second p-type well area 32 can be disposed at an opposite side of the n-type doping area 40.

In an embodiment, the first to fourth p-type doping areas 50, 110, 70, and 80 can be disposed on the n-type doping area 40, thereby helping to isolate the n-type doping area 40 from the upper surface of the semiconductor substrate 10.

The gate 60 can be disposed over a portion of the semiconductor substrate 10 in which the n-type doping area 40 makes contact with the second p-type well area 32. That is, a portion of the n-type doping area 40 can be disposed under a portion of the gate 60, and a portion of the second p-type well area 32 can be disposed under a portion of the gate 60. Also, the first p-type doping area 50 can be disposed between a portion of the gate 60 and a portion of the n-type doping area 40, thereby helping to isolate the n-type doping area 40 from the gate 60. In an embodiment, the first p-type doping area 50 can be adjacent to the second p-type well area 32.

In certain embodiments, a portion of the second p-type well area 32 below the gate 60 can be defined as the second p-type doping area 110. Thus, the second p-type doping area 110 can have an impurity concentration that is approximately the same as that of the second p-type well area 32.

The first and second p-type doping areas 50 and 110 can serve as a channel area. Also, the first p-type doping area 50 can have an impurity concentration higher than that of the second p-type doping area 110, and the third p-type doping area 70 can have an impurity concentration higher than that of the first p-type doping area 50. Additionally, the fourth p-type doping area 80 can have an impurity concentration higher than that of the third p-type doping area 70. That is, in an embodiment, the concentration of the p-type impurities can sequentially increase from the second p-type doping area 110 to the first p-type doping area 50 to the third p-type doping area 70 to the fourth p-type doping area 80.

Thus, the threshold voltage of the photodiode including the n-type doping area 40 can be higher than that of the floating diffusion area 100, so that charges of the channel area can be inhibited from flowing back toward the photodiode. Consequently, the quality of the image sensor can be improved by reducing the occurrence of noise and image lagging.

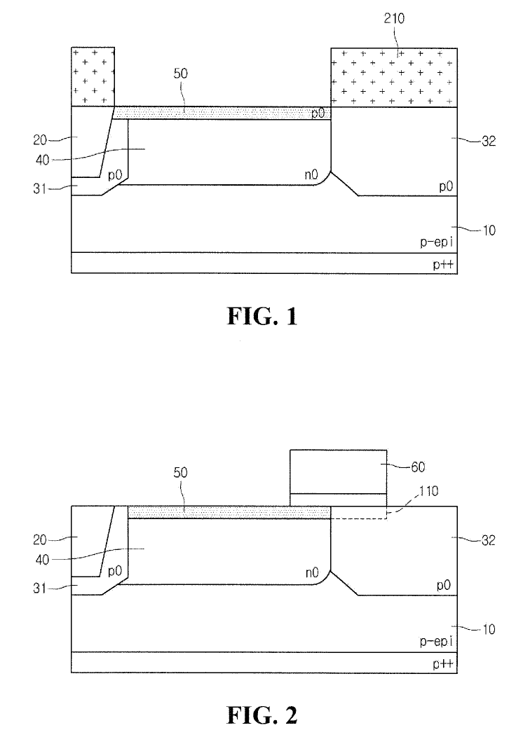

Additionally, according to embodiments of the present invention, an overlap area of the n-type doping area 40 and the gate 60 can be expanded, thereby improving the electron transmission efficiency. Hereinafter, manufacturing methods according to embodiments of the present invention will be described with reference to FIGS. 1 through 6.

Referring to FIG. 1, the r-type doping area 40 of the photodiode and the first p-type doping area 50 can be formed on the semiconductor substrate 10.

The semiconductor substrate 10 can be a heavily doped p-type substrate (p++) and can include a lightly doped p-type epitaxial layer. The lightly doped p-type epitaxial layer can be formed on the semiconductor substrate 10 through an epitaxial process.

The isolation layer 20 can be formed on the semiconductor substrate 10 to define the active area and the field area. The isolation layer 20 can be formed through, for example, a shallow trench isolation (STI) process.

The first p-type well area 31 and the second p-type well area 32 can be formed on the semiconductor substrate 10 and can help isolate the n-type doping area 40. The first p-type well area 31 can be formed adjacent to the isolation layer 20 and can help isolate the n-type doping area 40 from the isolation layer 20. The first p-type well area 31 can surround the isolation layer 20. The second p-type well area 32 can be formed spaced apart from the first p-type well area 31. In an embodiment, the n-type doping area 40 of the photodiode can be defined by the first and second p-type well areas 31 and 32. The first and second p-type well areas 31 and 32 can be formed with lightly doped p-type impurities p0.

In an embodiment, a first photoresist pattern 210 can be formed on the semiconductor substrate 10 exposing the surface of the semiconductor substrate 10 between the first and second p-type well areas 31 and 32.

Next, n-type impurities can be implanted using the first photoresist pattern 210 as an ion implantation mask. For example, the n-type doping area 40 can be formed by implanting phosphorus ions at an implantation energy of from about 50 keV to about 300 keV. As another example, the n-type doping area 40 can be formed by implanting arsenic ions at an implantation energy of from about 80 keV to about 360 keV.

Accordingly, the n-type doping area 40 can be formed between the first and second p-type well areas 31 and 32. Also, the n-type impurities of the n-type doping area 40 can be implanted at a high implantation energy, so that the n-type impurities can be formed in a deep area of the semiconductor substrate 10.

An annealing process can be performed, allowing the impurities in the n-type doping area 40 to diffuse.

Thereafter, the first p-type doping area 50 can be formed on the surface of the semiconductor substrate 10 by implanting p-type impurity ions. The first p-type doping area 50 can be formed by implanting lightly doped p-type impurities p0 using the first photoresist pattern 210 as an ion implantation mask. The first p-type doping area 50 can be formed using an ion implantation energy lower than that of the n-type doping area 40. Thus, the first p-type doping area 50 can be formed to a depth that is less than that of the n-type doping area 40. For example, the first p-type doping area 50 can be formed by implanting BF₂ ions at an implantation energy of from about 5 keV to about 80 keV. As another example, the first p-type doping area 50 can be formed by implanting boron ions at an implantation energy of from about 1.5 keV to about 30 keV.

In an embodiment, the first p-type doping area 50 can be formed adjacent to the second p-type well area 32 near the surface of the semiconductor substrate 10. Also, the n-type doping area 40 below the first p-type doping area 50 can also be formed adjacent to the second p-type well area 32.

The first p-type doping area 50 can have an impurity concentration higher than that of the second p-type well area 32.

According to certain embodiments, after forming the first and second p-type well areas 31 and 32, the n-type doping area 40 and the first p-type doping area 50 can be formed. In alternative embodiments, the first and second p-type well areas 31 and 32 can be formed after forming the n-type doping area 40 and the first p-type doping area 50.

Referring to FIG. 2, the gate 60 can be formed on the semiconductor substrate 10. The gate 60 can be, for example, the gate of a transfer transistor. The gate 60 can be formed through any suitable method known in the art. In one embodiment, the gate 60 can be formed by depositing a gate insulation layer and a gate conductive layer and then patterning them. For example, the gate conductive layer can be a single layer or a multi-layer using polysilicon, metal (such as tungsten), and metal silicide.

The gate 60 can be formed on a portion of the semiconductor substrate 10 such that it is over a point in which the first p-type doping area 50 is adjacent to the second p-type well area 32. That is, a portion of the gate 60 can be over a portion of the first p-type doping area 50, and another portion of the gate 60 can be over a portion of the second p-type well area 32.

Accordingly, a channel area can be formed by the first p-type doping area 50 and the second p-type well area 32 below the gate 60. Hereinafter, a portion of the second p-type well area 32 below the gate 60 will be referred to as the second p-type doping area 110. The first p-type doping area 50 of the channel area can have an impurity concentration higher than that of the second p-type doping area 110. In a specific embodiment, a portion of the first p-type doping area 50 below the gate 60 can have a width of about 0.5 μm.

As described above, since the gate 60 can be formed on the semiconductor substrate 10 after forming the n-type doping area 40, an overlap area of the gate 60 and the n-type doping area 40 can be controlled. Thus, diffusion of a channel inversion area into the surface of the semiconductor substrate 10 below the gate 60 can be controlled using gate voltage, so that the transmission properties between the channel area and the photodiode can be controlled using the gate voltage. Further, as an overlap area of the gate 60 and the n-type doping area 40 becomes larger, the overlap area can be controlled by a gate channel inversion field to improve the charge transmission efficiency.

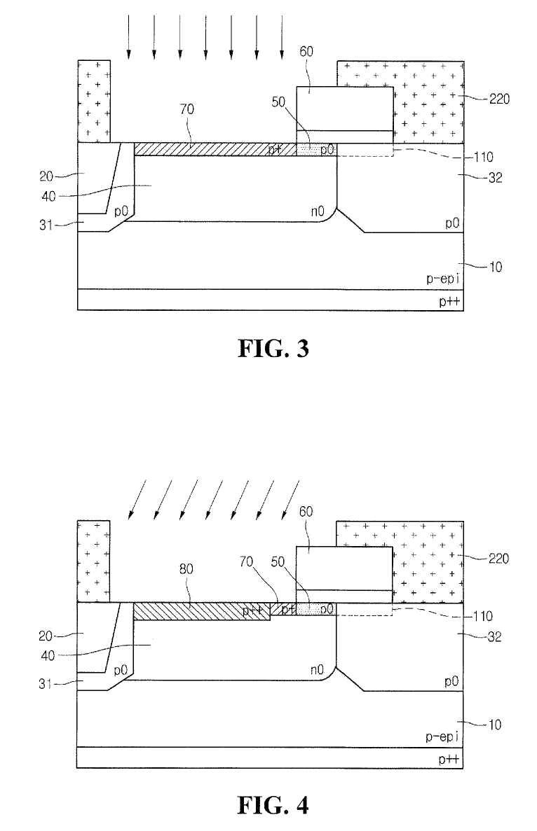

Referring to FIG. 3, the third p-type doping area 70 can be formed on the n-type doping area 40 at one side of the gate 60. The third p-type doping area 70 can be formed by implanting a p-type dopant having an intermediate concentration p+. For example, the third p-type doping area 70 can include BF₂ or boron ions. The third p-type doping area 70 can be formed by forming a second photoresist pattern 220 exposing the n-type doping area 40 on the semiconductor substrate 10 and then performing an ion implantation process using the second photoresist pattern 220 and the gate 60 as an ion implantation mask. In an embodiment, the ion implantation process of the third p-type doping area 70 can be performed with a tilt angle of from about 0° to about 10°. Accordingly, at least a majority of the third p-type doping area 70 can be formed at a side of the gate 60.

In an embodiment, the third p-type doping area 70 can be formed at an ion implantation energy similar to that of the first p-type doping area 50. Since the third p-type doping area 70 can be formed on the first p-type doping area 50 through ion implantation, the third p-type doping area 70 can have an impurity concentration higher than that of the first p-type doping area 50.

Accordingly, the third p-type doping area 70 can have a higher impurity concentration than that of the first p-type doping area 50, and the first p-type doping area 50 can have a higher impurity concentration than that of the second p-type doping area 110.

Referring to FIG. 4, the fourth p-type doping area 80 can be formed on the n-type doping area 40 at one side of the gate 60. The fourth p-type doping area 80 can be formed by implanting p-type impurities at a high concentration p++. For example, the fourth p-type doping area 80 can include BF₂ or boron ions.

In an embodiment, the fourth p-type doping area 80 can be formed through an ion implantation process using the second photoresist pattern 220 as an ion implantation mask. The ion implantation process of the fourth p-type doping area 80 can be performed with a tilt angle of from about 15° to about 45°. Thus, the fourth p-type doping area 80 can be spaced apart from the gate 60.

In an embodiment, the fourth p-type doping area 80 can be formed at an ion implantation energy similar to that of the first p-type doping area 50. Since the fourth p-type doping area 80 can be formed on the surface of the semiconductor substrate 10, in which the first and third p-type doping areas 50 and 70 are formed, the fourth p-type doping area 80 can have an impurity concentration higher than that of the first and third p-type doping areas 50 and 70.

Accordingly, fourth p-type doping area 80 can have a higher impurity concentration than that of the third p-type doping area 70, the third p-type doping area 70 can have a higher impurity concentration than that of the first p-type doping area 50, and the first p-type doping area 50 can have a higher impurity concentration than that of the second p-type doping area 110.

As described above, the first, third, and fourth p-type doping areas 50, 70, and 80 can be formed on the n-type doping area 40, thereby forming a photodiode having a PNP structure on the semiconductor substrate 10.

Referring to FIG. 5, spacers 90 can be formed at the lateral walls of the gate 60, and the floating diffusion area 100 for receiving photoelectrons generated from the photodiode can be formed at a side of the gate 60.

In an embodiment, a photoresist pattern (not shown) exposing a portion of the semiconductor substrate 10 at a side of the gate 60 can be formed, and then a lightly doped drain (LDD) area can formed using the photoresist pattern as an ion implantation mask. Next, the photoresist pattern can be removed and then the spacers 90 can be formed at the lateral walls of the gate 60. Th en, heavily doped n-type impurities can be implanted at a side of the gate 60 to form the floating diffusion area 100. In an alternate embodiment, the fourth p-type doping are 80 can be formed after forming the spacers 90 such that the spacers 90 can be used as part of the ion implantation mask.

According to embodiments of the present invention the profile of the p-type doping areas formed on the n-type doping area 40 has an impurity concentration that increases as it goes away from the gate 60. Thus, the threshold voltage of the p-type doping areas having a higher impurity concentration can be increased, so that charges can be inhibited from flowing back toward the photodiode.

FIG. 6(a) is a graph showing doping concentration as a function of position for an image sensor according to embodiment of the present invention. In FIG. 6(a), the x-axis represents the position of an impurity area formed in the semiconductor substrate, and the y-axis represents doping concentration. FIG. 6(b) is a graph showing potential as a function of position, and in FIG. 6(b), the x1-axis represents the position of an impurity area while the y1-axis represents potential.

Referring to FIG. 6(a), according to the profile of the p-type doping areas, the fourth p-type doping area 80 can have a high concentration p++, the third p-type doping area 70 can have an intermediate concentration p+, the first p-type doping area 50 can have a low concentration p0, and the second p-type doping area 110 can have a concentration p0 that is lower than that of the first p-type doping area 50.

Thus, since the first p-type doping area 50 of the channel area can have an impurity concentration higher than that of the second p-type doping area 110, the first p-type doping area 50 can have a higher threshold voltage.

Referring to FIG. 6(b), the potential can increase from the fourth p-type doping area 80 to the second p-type doping area 110. In particular, since the first p-type doping area 50 can have a higher impurity concentration than that of the second p-type doping area 110, the first p-type doping area 50 can have a lower potential level. Thus, when electrons generated from the n-type doping area 40 of the photodiode are transmitted to the floating diffusion area 100, the second p-type doping area 110 does not serve as a potential barrier.

That is, since the first p-type doping area 50 can have a higher impurity concentration than that of the second p-type doping area 110, the threshold voltage of the first p-type doping area 50 can be higher than that of the second p-type doping area 110. Thus, the first p-type doping area 50 can have a potential level lower than that of the second p-type doping area 110.

Consequently, when the transfer transistor is turned off, the electrons of the channel area can be inhibited from flowing back toward the photodiode, so that noise and image lagging can be reduced.

Additionally, since an overlap area of the n-type doping area 40 and the gate 60 can be expanded, the charge transmission characteristics can be enhanced even if the threshold voltage of the channel area is increased.

According to embodiments of the present invention, a connection part of the channel area and the photodiode can have a higher impurity concentration than that of a connection part of the channel area and the floating diffusion area. Thus, when the gate is turned off, the charges of the channel area can be inhibited from flowing back toward the photodiode, thereby reducing noise and image lagging.

Furthermore, the photodiode can be formed without using an additional mask process before the gate is formed, so that the overlap area of the gate and the n-type doping area can be better controlled. Thus, electrical connection of the photodiode can be controlled using the gate voltage to improve the electron transmission efficiency.

Moreover, according to embodiments of the present invention, the n-type doping area of the photodiode can be formed before the gate is formed, so that parasitic effects that may be caused by gate penetration can be inhibited and the n-type doping area can be formed at high energies.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a gate on a semiconductor substrate;
a first p-type doping area below the gate;
a second p-type doping area below the gate and adjacent to the first p-type doping area;
a third p-type doping area adjacent to the first p-type doping area at a side opposite to the second p-type doping area;
a fourth p-type doping area adjacent to the third p-type doping area;
an n-type doping area disposed in the semiconductor substrate such that at least a portion of the n-type doping area is below the first, third, and fourth p-type doping areas; and
a floating diffusion area at a side of the gate and contacting the second p-type doping area.

2. The image sensor according to claim 1, further comprising:
a first p-type well area disposed at a first side of the n-type doping area; and
a second p-type well area disposed at a second side of the n-type doping area.

3. The image sensor according to claim 2, wherein the second p-type doping area is provided as a portion of the second p-type well area.

4. The image sensor according to claim 2, wherein an impurity concentration of the second p-type doping area is approximately equal to an impurity concentration of the second p-type well area.

5. The image sensor according to claim 2, wherein an impurity concentration of the first p-type well area is approximately equal to an impurity concentration of the second p-type well area.

6. The image sensor according to claim 1, wherein an impurity concentration of the first p-type doping area is greater than an impurity concentration of the second p-type doping area.

7. The image sensor according to claim 6, wherein an impurity concentration of the third p-type doping area is greater than the impurity concentration of the first p-type doping area.

8. The image sensor according to claim 7, wherein an impurity concentration of the fourth p-type doping area is greater than the impurity concentration of the third p-type doping area.

9. A method of manufacturing an image sensor, comprising:
forming an n-type doping area in a semiconductor substrate;
forming a first p-type doping area on the n-type doping area;
forming a second p-type doping area in the semiconductor substrate, wherein the second p-type doping area is disposed at a first side of the first p-type doping area;
forming a gate on at least a portion of the first p-type doping area and at least a portion of the second p-type doping area;
forming a third p-type doping area on the n-type doping area and at a second side of the first p-type doping area;
forming a fourth p-type doping area on the n-type doping area and at a side of the third p-type doping area; and
forming a floating diffusion area at a side of the gate.

10. The method according to claim 9, further comprising:
forming a first p-type well area and a second p-type well area in the semiconductor substrate before forming the gate.

11. The method according to claim 10, wherein forming the n-type doping area comprises forming the n-type doping area between the first p-type well area and the second p-type well area.

12. The method according to claim 10, wherein the forming of the second p-type well area provides the second p-type doping area.

13. The method according to claim 12, wherein forming the floating diffusion are comprises implanting n-type impurities into the second p-type well area, wherein the floating diffusion area defines a side boundary of the second p-type doping area.

14. The method according to claim 10, wherein forming the first p-type doping area comprises:
forming a first photoresist pattern exposing at least a portion of the semiconductor substrate between the first p-type well area and the second p-type well area; and
implanting p-type impurities in the semiconductor substrate using the first photoresist pattern as an implantation mask.

15. The method according to claim 10, wherein forming the gate comprises forming the gate over a portion of the semiconductor substrate in which the n-type doping area is in contact with the second p-type well area.

16. The method according to claim 10, wherein forming the third p-type doping area comprises:
forming a second photoresist pattern exposing the first p-type doping area at a side of the gate; and
implanting p-type impurities in the first p-type doping area using the second photoresist pattern as an implantation mask.

17. The method according to claim 16, wherein implanting p-type impurities in the first p-type doping area using the second photoresist pattern as an implantation mask comprises implanting p-type impurities at a tilt angle of from about 0° to about 10°.

18. The method according to claim 16, wherein forming the fourth p-type doping area comprises implanting p-type impurities in the third p-type doping area using the second photoresist pattern as an implantation mask.

19. The method according to claim 18, wherein implanting p-type impurities in the third p-type doping area using the second photoresist pattern as an implantation mask comprises implanting p-type impurities at a tilt angle of from about 15° to about 45°.

20. The method according to claim 9, wherein an impurity concentration of the first p-type doping area is greater than an impurity concentration of the second p-type doping area.
